(19) United States
(12) Patent Application Publication
(10) Pub. No.: US 2026/0061972 A1
(43) Pub. Date: Mar. 5, 2026

(54) BATTERY REPLACEMENT METHOD

(71) Applicant: TOYOTA JIDOSHA KABUSHIKI KAISHA, Toyota-shi (JP)

(72) Inventors: Kenji TAKAHASHI, Toyota-shi (JP); Takenori Mikami, Miyoshi-shi (JP); Kenji BABA, Seto-shi (JP)

(73) Assignee: TOYOTA JIDOSHA KABUSHIKI KAISHA, Toyota-shi (JP)

(21) Appl. No.: 19/292,536

(22) Filed: Aug. 6, 2025

(30) Foreign Application Priority Data
Aug. 28, 2024 (JP) 2024-146695

(51) Int. Cl. B60S 5/06; B60K 1/04; G01R 31/392

(52) U.S. Cl. CPC B60S 5/06; B60K 1/04; G01R 31/392; B60K 2001/0483

(57) ABSTRACT

To provide a battery replacement method for determining a suitable frequency of replacing the batteries mounted in a stationary power supply. A battery replacement method for a battery-mounted housing implemented by a computer in which the housing includes: a plurality of mounting spaces that are formed to be alternately stacked in a front side and a rear side of the battery-mounted housing, each of the plurality of mounting spaces having a battery mounted therein; and a take-out port formed in the front side of the battery-mounted housing, the method including: a state acquisition procedure for acquiring an estimated deterioration state of at least one of the plurality of batteries mounted in the battery mounted-housing; and a determining procedure for determining that the battery for which the estimated deterioration state has been acquired be replaced or re-arranged based on the estimated deterioration state and a mounting position of the battery.

### CROSS REFERENCE TO RELATED APPLICATIONS

This application is based upon and claims the benefit of priority from Japanese patent application No. 2024-146695, filed on Aug. 28, 2024, the disclosure of which is incorporated herein in its entirety by reference.

### BACKGROUND

The present disclosure relates to a battery replacement method.

A stationary power supply is one of the reuses of vehicle-mounted batteries. In order to realize a stationary power supply with a high battery capacity by reusing vehicle-mounted batteries, it is necessary to store a plurality of vehicle-mounted batteries at a high mounting density in the stationary power supply housing. On the other hand, as the mounting density of vehicle-mounted batteries increases, the space allowance in the stationary power supply housing decreases. As a result, limitation imposed in replacing the mounted batteries increases, and the amount of work required per replacement operation increases. Therefore, it is required to minimize the frequency of replacing the mounted batteries and to reduce the amount of work required for managing a stationary power supply.

Patent Literature 1 discloses a method for replacing secondary batteries that constitute a battery pack, in which defective secondary batteries are judged in units of voltage detection block, and the battery that is judged to be defective and needs to be to be replaced is replaced with a replacement battery in units of voltage detection block.
[Patent Literature 1] Japanese Unexamined Patent Application Publication No. 2002-015781

### SUMMARY

In a battery pack in which a plurality of secondary batteries are electrically connected in series or in parallel, the secondary battery replacement method disclosed in Patent Literature 1 can reduce the cost of battery replacement without having to detect the voltages of all secondary batteries constituting the battery pack. However, there is no description in Patent Literature 1 as to determining the suitable frequency of replacing the secondary batteries constituting the battery pack based on the mounting position of the secondary batteries constituting the battery pack. Therefore, the secondary battery replacement method disclosed in Patent Literature 1 cannot determine the suitable frequency of replacing the batteries mounted in a power supply in the case of a stationary power supply in which the amount of work required to replace the mounted batteries differs depending on the mounting positions thereof, and therefore cannot reduce the amount of work required to replace the mounted batteries.

In view of the problems described above, an object of this disclosure is to provide a battery replacement method for determining the suitable frequency of replacing the batteries mounted in a stationary power supply in which the amount work required to replace the mounted batteries differ depending on the mounting positions thereof.

According to an aspect of the present disclosure, a battery replacement method for a battery-mounted housing implemented by a computer includes a state acquisition procedure and a determining procedure. The battery-mounted housing includes: a plurality of mounting spaces that are formed to be alternately stacked in a front side and a rear side of the battery-mounted housing, each of the plurality of mounting spaces having a battery mounted therein; and a take-out port for taking-out the batteries formed in the front side of the battery-mounted housing. In the state acquisition procedure, an estimated deterioration state of at least one of the plurality of batteries mounted in the battery mounted-housing is acquired. In the determining procedure, the battery for which the estimated deterioration state has been acquired is replaced or re-arranged based on the estimated deterioration state and a mounting position of the battery.

In the determining procedure of the battery replacement method described above, in the case where the estimated deterioration state of the battery which is mounted in the front side of the battery-mounted housing has met a first judgement criterion, it may be determined the battery which is mounted in the front side of the battery-mounted housing and the estimated deterioration state of which has met the first judgement criterion be replaced. In the case where the estimated deterioration state of the battery which is mounted in the rear side of the battery-mounted housing has met a second judgement criterion, it is determined that the battery which is mounted in the rear side of the battery-mounted housing and the estimated deterioration state of which has met the second judgement criterion be replaced. In this case, the second judgement criterion is less strict than the first judgement criterion.

In the determining procedure of the battery replacement method described above, in the case where the estimated deterioration state of the battery which is mounted in the rear side of the battery-mounted housing has met a third judgement criterion, it may be determined that the battery which is mounted in the rear side of the battery-mounted housing and the estimated deterioration state of which has met the third judgement criterion be re-arranged to the front side of the battery-mounted housing. In this case, the third judgement criterion is less strict than the second judgement criterion.

In determining procedure of the battery replacement method described above, in the case where it is determined that the at least one of the plurality of the batteries be replaced and the estimated deterioration state of the batteries other than the at least one of the plurality of the batteries determined to be replaced meet the fourth judgement criterion, it may be determined that the batteries whose estimated deterioration state meets the fourth judgement criterion be replaced.

In the battery replacement method described above, the battery is a vehicle-mounted battery and has an interference part, in which in taking out the battery mounted in the rear side of the battery-mounted housing from the take-out port of the battery-mounted housing, the interference part may interfere with the battery-mounted housing or the battery mounted in the front side of the battery-mounted housing.

According to the present disclosure, it is possible to provide a battery replacement method for determining a suitable frequency of replacing the batteries mounted in a stationary power supply in which the amount work required to replace the mounted batteries differ depending on the mounting positions thereof.

The above and other objects, features and advantages of the present disclosure will become more fully understood from the detailed description given hereinbelow and the accompanying drawings.

### BRIEF DESCRIPTION OF DRAWINGS

FIG. 1 is a configuration diagram of a stationary power supply 1 according to a first embodiment;

FIG. 2 is a first flowchart of a battery replacement method of batteries 11 according to the first embodiment;

FIG. 3 is a second flowchart of a battery replacement method of the batteries 11 according to a second embodiment;

FIG. 4 is a third flowchart of a battery replacement method of the batteries 11 according to a third embodiment; and

FIG. 5 is a fourth flowchart of a battery replacement method of the batteries 11 according to a fourth embodiment.

### DESCRIPTION OF EMBODIMENTS

Hereinafter, the present disclosure will be described through embodiments, but the claimed disclosure is not limited to the following embodiments. In addition, not all of the configurations described in the embodiments are essential as means for solving the problem. In order to clarify the description, the following descriptions and drawings are omitted and simplified as appropriate. In each of the drawings, the same reference numerals denote the same elements, and duplicate descriptions are omitted as necessary.

### First Embodiment

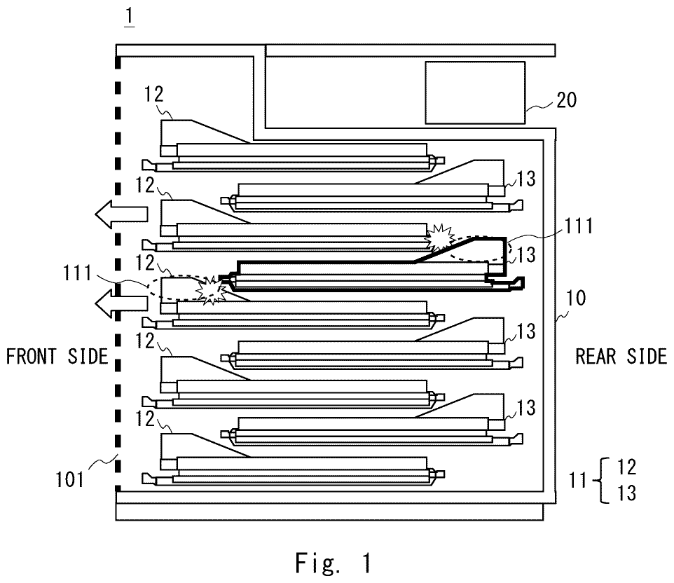

A first embodiment according to the present disclosure will be described with reference to FIG. 1. FIG. 1 is a configuration diagram of a stationary power supply 1 according to a first embodiment. The stationary power supply 1 is configured of a battery-mounted housing 10 in which a plurality of batteries 11 are mounted, and functions as a power supply. The stationary power supply 1 is used, for example, as a regulator for unstable power supply or an emergency battery for backup. The stationary power supply 1 mainly includes the battery-mounted housing 10, the batteries 11, a temperature control unit 20, and a computer (not shown).

The battery-mounted housing 10 is a housing for mounting the batteries 11. The battery-mounted housing 10 includes a plurality of mounting spaces for mounting batteries. Each of the plurality of mounting spaces includes a battery 11 mounted therein. In addition, the battery-mounted housing 10 includes, in the front side thereof, a take-out port 101 for taking-out the batteries 11. The mounting spaces are formed to be alternately stacked in the front side and the rear side of the battery-mounted housing 10, the front side being the side near the take-out port 101 and the rear side being the side spaced away from the take-out port 101. Therefore, a battery 11 can be taken out by moving it in the direction of the take-out port 101 formed in the front side of the battery-mounted housing 10, as indicated by the white arrow in FIG. 1. The take-out port 101 cannot be formed in the rear side of the battery-mounted housing 10 due to installation site restrictions and the like of the battery-mounted housing 10.

The battery-mounted housing 10 includes a plurality of mounting spaces. In FIG. 1, the battery-mounted housing 10 includes five mounting spaces formed in the front side thereof and four mounting spaces formed in the rear side thereof. Here, the lowermost mounting space is formed in the front side of the battery-mounted housing, and then mounting spaces are formed thereon alternately in the rear side and the front side of the battery-mounted housing. In FIG. 1, there are nine mounting spaces, and the uppermost mounting space is formed in the front side of the battery-mounted housing.

The stationary power supply 1 includes the plurality of batteries 11 mounted therein that are used as a power source. The batteries 11 are, for example, vehicle-mounted batteries. Here, the vehicle-mounted batteries may be reused. The batteries 11 include a front-side battery 12 and a rear-side battery 13. The front-side battery 12 is mounted in the mounting space formed in the front side of the battery-mounted housing 10 (hereinafter referred to as the front-side mounting space). The rear-side battery 13 is mounted in the mounting space formed in the rear side of the battery-mounted housing 10 (hereinafter referred to as the rear-side mounting space). The front-side battery 12 and the rear-side battery 13 are the same type of batteries. The front-side battery 12 and the rear-side battery 13 may be different types of batteries.

Each battery 11 has an interference part 111. In taking out the rear-side battery 13 from the take-out port 101 of the battery-mounted housing 10, the interference part 111 interferes with the front-side battery 12 or the battery-mounted housing 10. Therefore, in the case where a rear-side battery 13 is to be taken out, it is required to take out the front-side batteries 12 which are adjacent above and below the rear-side battery 13 to be taken out and before taking out the rear-side battery 13.

For example, as shown in FIG. 1, the interference part 111 is an end part of the battery 11 that is increased in thickness. In order to improve the mounting density of the batteries 11, the mounting spaces in the battery-mounted housing 10 are formed so that the interference part 111 do not overlap the part of the batteries 11 that overlap each other (hereinafter referred to as the overlapping part of the batteries 11). Therefore, in the battery-mounted housing 10, the battery 11 is installed so that the interference part 111 of the front-side battery 12 and the interference part 111 of the rear-side battery 13 project from overlapping part of the front-side battery 12 and the rear-side battery 13 to the front side and the rear side of the battery-mounted housing 10, respectively. Also, the front-side battery 12 and rear-side battery 13 are mounted in such a way that the front-side battery 12 and the rear-side battery 13 overlap each other in most parts thereof. Thus, even in the case where a large number of the batteries 11 are mounted in the battery-mounted housing 10, the installation area thereof can be reduced.

In this case, in order to improve the mounting density, the distance in the height direction of the overlapping part of the batteries 11 is shorter than the thickness increment of the interference part 111. Therefore, in the case where the rear-side battery 13 is taken out from the take-out port 101, it interferes with the front-side batteries 12 which are adjacent above and below the rear-side battery 13 to be taken out. Specifically, the rear-side battery 13 interferes with the interference part 111 of the front-side battery 12 which is adjacent below the rear-side battery 13. Also, the interference part 111 of the rear-side battery 13 interferes with the front-side battery 12 which is adjacent above the rear-side battery 13. Therefore, in the case where the rear-side battery 13 is taken out, the front-side batteries 12 which are adjacent above and below the rear-side battery 13 to be taken out must be taken out first.

Even in the case where the battery 11 does not include the interference part 111, it is difficult to take out the rear-side battery 13 without taking out the front-side battery 12 in the battery-mounted housing 10 in which the batteries are mounted at a high density. Similarly, even in the case where the distance in the height direction of the overlapping part of the batteries 11 is longer than the thickness increment of the interference part 111, it is difficult to take out the rear-side battery 13 without taking out the front-side battery 12 in the battery-mounted housing 10 in which the batteries 11 are mounted at a high density. In order to reduce the possibility of damage due to interference, the front-side batteries 12 which are adjacent above and below the rear-side battery 13 to be taken out need to be taken out first before taking out the rear-side battery 13 to be taken out.

As described above, in replacing the rear-side battery 13, it is necessary to take out the front-side batteries 12 which are adjacent above and below the rear-side battery 13 to be replaced, and the amount of work required for replacing the rear-side battery 13 increases compared to that for replacing the front-side battery 12. Therefore, it is particularly desired to reduce the frequency of replacing the rear-side batteries 13.

In order to obtain the estimated deterioration state of the batteries 11, the stationary power supply 1 may obtain measurement information such as input/output of the batteries 11, temperature of the batteries 11, and the like. For example, the stationary power supply 1 measures at least one of the input voltage, the input current, the output voltage, and the output current of the batteries 11 by an ammeter or a voltmeter. In addition, in the stationary power supply 1, a temperature sensor installed in the batteries 11 for obtaining temperature information thereof, for example.

The temperature control unit 20 controls the temperature of the stationary power supply 1. More specifically, the temperature rise of the batteries 11 is suppressed by the temperature control unit 20. In the case where the temperature of the batteries 11 is low, it is heated. The temperature control unit 20 is also referred to as a temperature control unit.

The computer (not shown) controls the input/output of the batteries 11 mounted in the stationary power supply 1. The computer may obtain estimated deterioration state of at least one of the plurality of the batteries 11 mounted in the stationary power supply 1. The computer may also output at least one of the information related to the stationary power supply 1 and the input/output state of the mounted batteries 11.

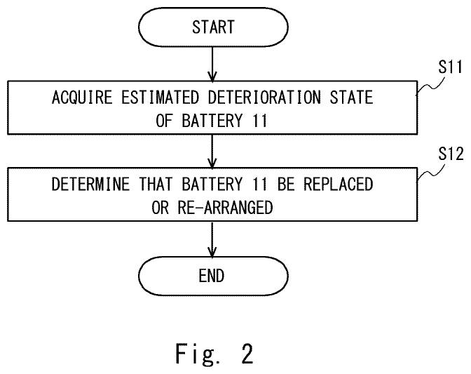

FIG. 2 is a first flowchart of a battery replacement method of the batteries 11 according to the first embodiment. The first flow includes Steps S11 and S12.

Step S11 is a state acquisition procedure. In Step S11, the computer acquires an estimated deterioration state of at least one of the plurality of batteries 11 mounted in the stationary power supply 1. The estimated deterioration state is acquired from the measurement results such as input/output information or temperature information pertaining to the batteries 11.

Step S12 is a determining procedure. In Step S12, the computer determines that the battery 11 be replaced or re-arranged based on the estimated deterioration state and the mounting position of the battery 11.

Upon termination of Step S12, the first flow of the battery replacement method for the stationary power supply 1 is terminated. After termination of the first flow, the stationary power supply 1 may output the information determined in the determining procedure of Step S12. With this configuration, the stationary power supply 1 according to the present embodiment can determine the suitable frequency of replacing the batteries 11 based on the estimated deterioration state of the mounted batteries 11.

The stationary power supply 1 may include a processor and a storage device in its configuration (not shown). The storage device of the stationary power supply 1 includes, for example, a storage device including a nonvolatile memory such as a flash memory or an SSD (Solid State Drive). In this case, the storage device stores a computer program (henceforth also referred to simply as a program) for executing the method described above. The processor reads the computer program from the storage device into a buffer memory such as a DRAM (Dynamic Random Access Memory) and executes the program.

The stationary power supply 1 may be connected to a network and execute the program by discrete processing such as cloud computing.

### Second Embodiment

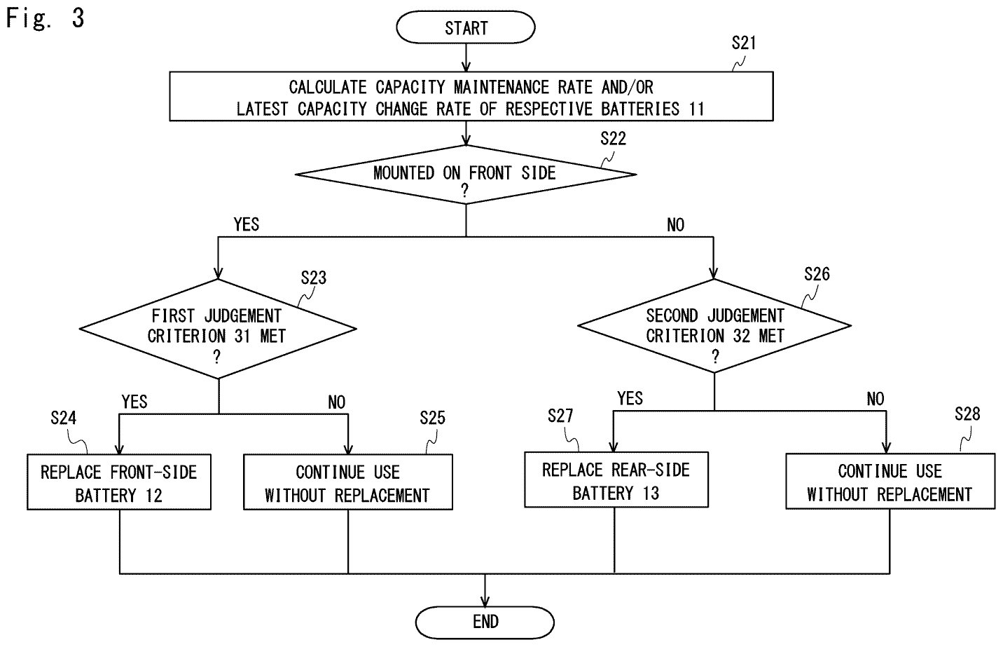

FIG. 3 is a second flowchart of a battery replacement method of batteries 11 according to a second embodiment. In the second flow, the battery 11 to be replaced is determined. Here, the second flow is applied to the stationary power supply 1 in FIG. 1. Therefore, the description of the configuration of the stationary power supply 1 described with reference to FIG. 1 is omitted.

The second flow includes Steps S21 to S28. Note that Step S21 corresponds to the state acquisition procedure of Step S11 described with reference to FIG. 2. Steps S22 to S28 correspond to the determining procedure of Step S12 described with reference to FIG. 2.

In Step S21, the computer calculates at least one of the capacity maintenance rate and the latest capacity change rate of the respective batteries. The capacity maintenance rate is the ratio of the current battery capacity of the battery 11 to the battery capacity according to the specifications of the battery 11. The capacity maintenance rate may be the ratio of the current battery capacity of the battery 11 to the battery capacity immediately after replacement of the battery 11. The capacity change rate is the amount of change in the capacity maintenance rate of the battery 11 over time. The computer treats at least one of the calculated capacity maintenance rate and the latest capacity change rate as the estimated deterioration state. The computer may calculate the estimated replacement timing of the respective batteries 11 from at least one of the capacity maintenance rate and the latest capacity change rate, and treat the estimated replacement timing as the estimated deterioration state.

Step S21 is started every predetermined period. The predetermined period is, for example, one day, one week, or one month. Step S21 may be started in the case where a battery 11 for replacement yet to be mounted is prepared.

In Step S22, the computer makes a judgement as to whether the mounting position of the battery 11 to be replaced is in the front side of the battery-mounted housing 10. The computer obtains the mounting position of the battery 11 to be replaced. In the case where the mounting position of the battery 11 is in the front side of the battery-mounted housing 10, the computer starts Step S23. Otherwise, the computer starts Step S26. In other words, the computer performs processing starting from Step S23 for the front-side battery 12 and processing starting from Step S26 for the rear-side battery 13.

Step S23 is started in the case where a judgement that the battery 11 is arranged in the front side of the battery-mounted housing 10 is made. In Step S23, the computer judges whether the estimated deterioration state of the front-side battery 12 has met the first judgement criterion 31. The first judgement criterion 31 is a predetermined threshold value based on the history data on the replacement of batteries. The first judgement criterion 31 may be determined based on the state of the stationary power supply 1 and the state of the respective members included in the stationary power supply 1. In the case where the estimated deterioration state of the front-side battery 12 meets the first judgement criterion 31, the computer starts Step S24. Otherwise, the computer starts Step S25.

In Step S24, the computer determines that the front-side battery 12 be replaced, and outputs a replacement signal of the front-side battery 12 to be replaced. The computer may send a predetermined notification to an external device connected thereto as an output of the replacement signal. The computer may include a buzzer and cause the buzzer to emit a sound in a predetermined manner as an output of the replacement signal. The computer may include a notification light and turn on the notification light in a predetermined manner as an output of the replacement signal. In Step S25, the computer terminates the series of processing without outputting the replacement signal. Upon completion of Step S24 or Step S25, the computer terminates the second flow.

Here, the first judgement criterion 31 is, for example, that the current capacity maintenance rate of the front-side battery 12 is less than 60% of the battery capacity according to the specifications of the battery 12. With this configuration, the stationary power supply 1 can determine that the front-side battery 12 whose capacity maintenance rate has decreased be replaced. The first judgement criterion 31 is, for example, that the latest capacity change rate of the front-side battery 12 is 10% or higher. With this configuration, the stationary power supply 1 can determine that the front-side battery 12, which has rapidly deteriorated, be replaced.

The first judgement criterion 31 is, for example, that the estimated replacement timing of the front-side battery 12 is within one month from now (i.e., the present time). With this configuration, the stationary power supply 1 can determine that the front-side battery 12, which needs to be replaced by the next inspection cycle, be replaced.

Step S26 is started in the case where a judgement that the battery 11 is arranged in the rear side is made. In Step S26, the computer judges whether the estimated deterioration state of the rear-side battery 13 has met the second judgement criterion 32. The second judgement criterion 32 is a predetermined threshold value based on the history data on the replacement of batteries. The second judgement criterion 32 may be determined based on the state of the stationary power supply 1 and the state of the respective members included in the stationary power supply 1. In the case where the estimated deterioration state of the rear-side battery 13 meets the second judgement criterion 32, the computer starts Step S27. Otherwise, the computer starts Step S28. Note that the second judgement criterion 32 is less strict than the first judgement criterion 31.

In Step S27, the computer determines that the rear-side battery 13 be replaced, and outputs a replacement signal of the rear-side battery 13 to be replaced. The computer may send a predetermined notification to an external device connected thereto as an output of the replacement signal. The computer may include a buzzer and cause the buzzer to emit a sound in a predetermined manner as an output of the replacement signal. The computer may include a notification light and turn on the notification light in a predetermined manner as an output of the replacement signal. In Step S28, the computer terminates the series of processing without outputting a replacement signal. Upon completion of Step S27 or Step S28, the computer terminates the second flow.

The second judgement criterion 32 is, for example, that the current capacity maintenance rate of the rear-side battery 13 is less than 70% of the battery capacity according to the specifications of the battery 13. With this configuration, the stationary power supply 1 can determine that the rear-side battery 13, whose capacity maintenance rate is declining, be replaced and can set a replacement timing earlier than that of the front-side battery 12. The second judgement criterion 32 is, for example, that the latest capacity change rate of the rear-side battery 13 is 8% or higher. With this configuration, the stationary power supply 1 can manage the deteriorated rear-side battery 13 with higher precision compared to management of the front-side battery 12.

The second judgement criterion 32 is, for example, that the estimated replacement timing of the rear-side battery 13 is within two months from now (i.e., the present time). With this configuration, the stationary power supply 1 can determine that the rear-side battery 13 be replaced in good time.

As described above, according to the second flow of battery replacement method including Steps S21 to S28, the stationary power supply 1 of the present embodiment can determine that the batteries 11 be replaced using the judgement criterion of replacement of the batteries according to the mounting position of the respective batteries 11. With this configuration, the stationary power supply 1 can determine the suitable frequency of replacing the batteries based on the estimated deterioration state of the mounted batteries 11.

### Third Embodiment

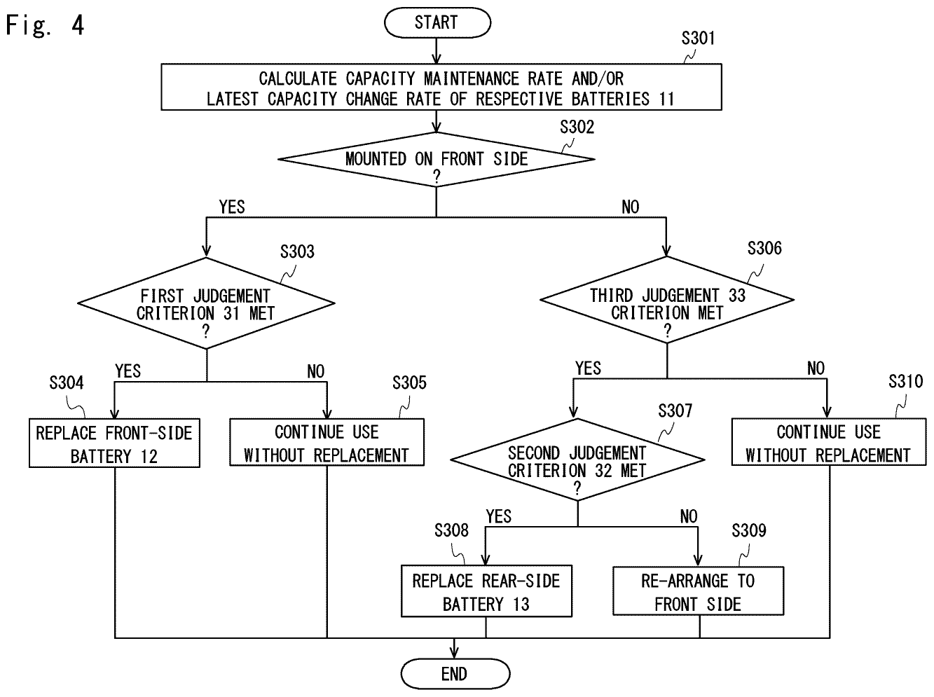

FIG. 4 is a third flowchart of a battery replacement method of the batteries 11 according to a third embodiment. In the third flow, the battery 11 to be replaced or re-arranged is determined. Here, the third flow is applied to the stationary power supply 1 in FIG. 1. Therefore, the description of the configuration of the stationary power supply 1 described with reference to FIG. 1 is omitted.

The third flow includes Steps S301 to S310. Note that Step S301 corresponds to the state acquisition procedure of Step S11 described with reference to FIG. 2. Steps S302 to S310 correspond to the determining procedure of Step S12 described with reference to FIG. 2. Note that Steps S301 to S305 correspond to Steps S21 to S25 in the second flow of the battery replacement method described with reference to FIG. 3. Therefore, the description of Steps S301 to S305 is omitted.

Step S306 is started in the case where a judgement that the battery 11 is arranged in the rear side of the battery-mounted housing 10 is made. In Step S306, the computer judges whether the estimated deterioration state of the rear-side battery 13 has met the third judgement criterion 33. The third judgement criterion 33 is a predetermined threshold value based on the history data on the replacement of batteries. The third judgement criterion 33 may be determined based on the state of the stationary power supply 1 and the state of the respective members included in the stationary power supply 1. In the case where the estimated deterioration state of the rear-side battery 13 meets the third judgement criterion 33, the computer starts Step S307. Otherwise, the computer starts Step S310. Note that the third judgement criterion 33 is less strict than the first judgement criterion 31.

In Step S307, the computer judges whether the estimated deterioration state of the rear-side battery 13 has met the second judgement criterion 32. The second judgement criterion 32 is a predetermined threshold value based on the history data on the replacement of batteries. The second judgement criterion 32 may be determined based on the state of the stationary power supply 1 and the state of the respective members included in the stationary power supply 1. In the case where the estimated deterioration state of the rear-side battery 13 has met the second judgement criterion 32, the computer starts Step S308. Otherwise, the computer starts Step S309. Note that the second judgement criterion 32 is less strict than the first judgement criterion 31. The third judgement criterion 33 is less strict than the second judgement criterion 32.

In other words, the computer executes the processing of Step S308 for the rear-side battery 13 that has met the second judgement criterion 32, and executes the processing of Step S309 for the rear-side battery 13 that has met only the third judgement criterion 33 without meeting the second judgement criterion 32.

In Step S308, the computer determines that the rear-side battery 13 that has met the second judgement criterion 32 be replaced, and outputs a replacement signal of the rear-side battery 13 to be replaced. In Step S309, the computer determines that the rear-side battery 13 that has met the third judgement criterion 33 be re-arranged to the front-side mounting space, and outputs a re-arrangement signal of the rear-side battery 13 to be replaced. The computer may send a predetermined notification to an external device connected thereto as an output of the re-arrangement signal or the re-arrangement signal. The computer may include a buzzer and cause the buzzer to emit a sound in a predetermined manner as an output of the replacement signal or the re-arrangement signal. The computer may include a notification light and turn on the notification light in a predetermined manner as an output of the replacement signal or the re-arrangement signal. Upon completion of Step S308 or Step S309, the computer terminates the third flow.

The third judgement criterion 33 is, for example, that the current capacity maintenance rate of the rear-side battery 13 is less than 75% of the battery capacity according to the specifications of the battery 13. With this configuration, the stationary power supply 1 can determine that the rear-side battery 13 whose capacity maintenance rate has started to decrease be replaced, and can arrange the battery 11, the replacement timing of which is nearing, to the front side of the battery-mounted housing 10 where it can be taken out easily. The third judgement criterion 33 is, for example, that the latest capacity change rate of the rear-side battery 13 is 5% or higher. With this configuration, the stationary power supply 1 can arrange the rear-side battery 13, the deterioration of which is likely to occur, to the front side of the battery-mounted housing 10.

The third judgement criterion 33 is, for example, that the estimated replacement timing of the rear-side battery 13 is within two and a half months from now (i.e., the present time). With this configuration, the stationary power supply 1 can arrange the rear-side battery 13, the replacement timing of which is nearing, to the front side of the battery-mounted housing 10.

In Step S310, the computer terminates the series of processing without outputting a replacement signal or a re-arrangement signal. Upon completion of Step S310, the computer terminates the third flow.

As described above, according to the third flow of the battery replacement method including Steps S301 to S310, the stationary power supply 1 of the present embodiment can set the judgement criterion for replacement and re-arrangement of the respective batteries according to the mounting position of the respective batteries 11. With this configuration, the stationary power supply 1 can determine the suitable frequency of replacing the batteries based on the estimated deterioration state of the mounted batteries 11. The stationary power supply 1 can determine the suitable arrangement of the batteries 11 based on the estimated deterioration state of the mounted batteries 11.

### Fourth Embodiment

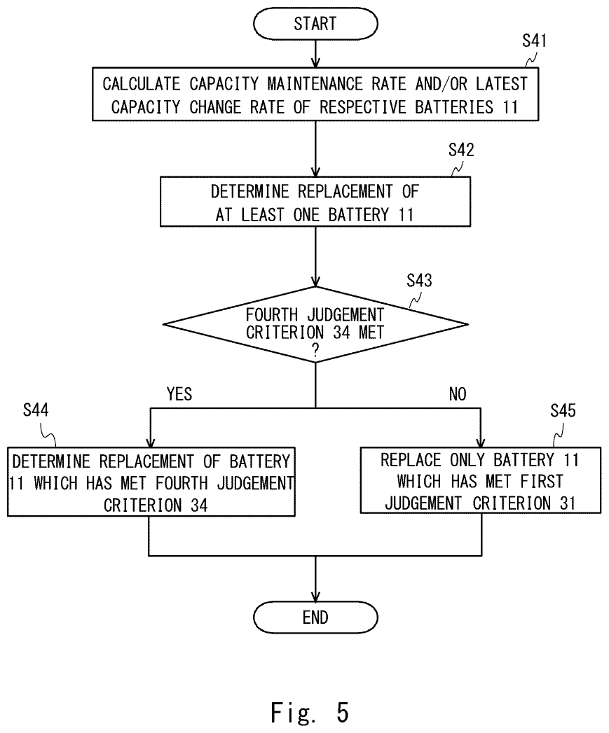

FIG. 5 is a fourth flowchart of a battery replacement method of the batteries 11 according to a fourth embodiment. In the fourth flow, the batteries 11 to be replaced are determined collectively upon replacement of the batteries. Here, the fourth flow is applied to the stationary power supply 1 in FIG. 1.

The fourth flow includes Steps S41 to S45. Note that Step S41 corresponds to the state acquisition procedure of Step S11 described with reference to FIG. 2. Steps S42 to S45 correspond to the determining procedure of Step S12 described with reference to FIG. 2.

In Step S41, the computer calculates at least one of the capacity maintenance rate and the latest capacity change rate of the respective batteries. The capacity maintenance rate is the ratio of the current battery capacity of the battery 11 to the battery capacity according to the specifications of the battery 11. The capacity maintenance rate may be the ratio of the current battery capacity of the battery 11 to the battery capacity of the battery 11 immediately after replacement of the battery 11. The capacity change rate is the amount of change in the capacity maintenance rate of the battery 11 over time. The computer treats at least one of the calculated capacity maintenance rate and the latest capacity change rate as the estimated deterioration state. The computer may calculate the estimated replacement timing of the respective batteries 11 from at least one of the capacity maintenance rate and the latest capacity change rate, and treat the estimated replacement timing as the estimated deterioration state.

In Step S42, the computer determines that at least one battery 11 of the plurality of batteries 11 be replaced. The computer starts Step S43 in the case where it is determined that at least one battery 11 out of the plurality of batteries 11 be replaced.

Step S43 is started in the case where the computer determines that at least one battery 11 out of the plurality of batteries 11 be replaced. In Step S43, the computer judges whether the estimated deterioration state of the respective batteries 11 other than the battery 11 determined to be replaced has met the fourth judgement criterion 34. The fourth judgement criterion 34 is a predetermined threshold value based on the history data on the replacement of batteries. The fourth judgement criterion 34 may be determined based on the state of the stationary power supply 1 and the state of the respective members included in stationary the power supply 1. In the case where the estimated deterioration state of the respective batteries 11 other than the battery 11 determined to be replaced has met the fourth judgement criterion 34, the computer starts Step S44. Otherwise, the computer starts Step S45. Note that the fourth judgement criterion 34 may be less strict than the judgement criterion used in Step S42.

In Step S44, the computer determines that not only the battery satisfying the first judgement criterion 31 be replaced but also the battery 11 which meets the fourth judgement criterion 34 be replaced, and outputs a replacement signal of the battery 11 to be replaced. In Step S45, the computer outputs a replacement signal only for the battery 11 meeting the first judgement criterion 31. The computer may send a predetermined notification to an external device connected thereto as the output of the replacement signal. The computer includes a buzzer and may cause the buzzer to emit a sound in a predetermined manner as an output of the replacement signal. The computer includes a notification light and may turn on the notification light in a predetermined manner as an output of the replacement signal. Upon completion of Step S44 or Step S45, the computer terminates the fourth flow.

The fourth judgement criterion 34 is, for example, that the current capacity maintenance rate of the battery 11 is less than 70% of the battery capacity according to the specifications of the battery 11. The fourth judgement criterion 34 is, for example, that the latest capacity change rate of the battery 11 is 8% or higher. The fourth judgement criterion 34 is, for example, that estimated replacement timing of the battery 11 is within 2 months from now (i.e., the present time). With this configuration, the stationary power supply 1 can collectively determine that the batteries 11 that are estimated to require replacement in the near future be replaced. Therefore, the stationary power supply 1 can reduce the replacement frequency of the batteries 11.

As described above, the stationary power supply 1 of the present embodiment judges which batteries 11 should be replaced collectively based on the estimated deterioration state according to the fourth flow of the battery replacement method including Steps S41 to S45. With this configuration, the stationary power supply 1 can collectively replace the batteries 11 that are estimated to require replacement in the near future, thereby reducing the replacement frequency.

It should be noted that the present disclosure is not limited to the above-described embodiments, and may be appropriately modified without departing from the gist of the present disclosure. For example, different criterions may be set for the fourth judgement criterion 34 of the front-side battery 12 and the fourth judgement criterion 34 of the rear-side battery 13. In addition, in the battery 11 in the vicinity of the battery 11 that meets the first judgement criterion 31, judgement criterion may be lowered to determine replacement thereof.

The program includes instructions (or software codes) that, when loaded into a computer, cause the computer to perform one or more of the functions described in the embodiments. The program may be stored in a non-transitory computer readable medium or a tangible storage medium. By way of example, and not limitation, non-transitory computer readable media or tangible storage media can include a random-access memory (RAM), a read-only memory (ROM), a flash memory, a solid-state drive (SSD) or other memory technologies, CD-ROM, digital versatile disc (DVD), Blu-ray (registered trademark) disc or other optical disc storage, magnetic cassettes, magnetic tape, magnetic disk storage or other magnetic storage devices. The program may be transmitted on a transitory computer readable medium or a communication medium. By way of example, and not limitation, transitory computer readable media or communication media can include electrical, optical, acoustical, or other forms of propagated signals.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A battery replacement method for a battery-mounted housing implemented by a computer in which the housing comprises:
a plurality of mounting spaces that are formed to be alternately stacked in a front side and a rear side of the battery-mounted housing, each of the plurality of mounting spaces having a battery mounted therein; and
a take-out port for taking-out the batteries formed in the front side of the battery-mounted housing,
the method comprising:
a state acquisition procedure for acquiring an estimated deterioration state of at least one of the plurality of batteries mounted in the battery mounted-housing; and
a determining procedure for determining that the battery for which the estimated deterioration state has been acquired be replaced or re-arranged based on the estimated deterioration state and a mounting position of the battery.

2. The battery replacement method according to claim 1, wherein in the determining procedure,
in the case where the estimated deterioration state of the battery which is mounted in the front side of the battery-mounted housing has met a first judgement criterion, it is determined that the battery which is mounted in the front side of the battery-mounted housing and the estimated deterioration state of which has met the first judgement criterion be replaced,
in the case where the estimated deterioration state of the battery which is mounted in the rear side of the battery-mounted housing has met a second judgement criterion, it is determined that the battery which is mounted in the rear side of the battery-mounted housing and the estimated deterioration state of which has met the second judgement criterion be replaced,
wherein the second judgement criterion is less strict than the first judgement criterion.

3. The battery replacement method according to claim 2, wherein in the determining procedure,
in the case where the estimated deterioration state of the battery which is mounted in the rear side of the battery-mounted housing has met a third judgement criterion, it is determined that the battery which is mounted in the rear side of the battery-mounted housing and the estimated deterioration state of which has met the third judgement criterion be re-arranged to the front side of the battery-mounted housing,
wherein the third judgement criterion is less strict than the second judgement criterion.

4. The battery replacement method according to claim 1, wherein in the determining procedure, in the case where it is determined that the at least one of the plurality of the batteries be replaced and the estimated deterioration state of the batteries other than the at least one of the plurality of the batteries determined to be replaced meet the fourth judgement criterion, it is determined that the batteries whose estimated deterioration state meets the fourth judgement criterion be replaced.

5. The battery replacement method according to claim 1,
wherein the battery is a vehicle-mounted battery and has an interference part,
wherein in taking out the battery mounted in the rear side of the battery-mounted housing from the take-out port of the battery-mounted housing, the interference part interferes with the battery-mounted housing or the battery mounted in the front side of the battery-mounted housing.
